(19) United States
(12) Patent Application Publication
(10) Pub. No.: US 2013/0260501 A1
(43) Pub. Date: Oct. 3, 2013

(54) VAPOR DEPOSITION DEVICE, VAPOR DEPOSITION METHOD, AND METHOD OF MANUFACTURING ORGANIC ELECTROLUMINESCENT DISPLAY DEVICE

(71) Applicants: Tohru Sonoda, Osaka (JP); Shinichi Kawato, Osaka (JP); Satoshi Inoue, Osaka (JP); Satoshi Hashimoto, Osaka (JP)

(72) Inventors: Tohru Sonoda, Osaka (JP); Shinichi Kawato, Osaka (JP); Satoshi Inoue, Osaka (JP); Satoshi Hashimoto, Osaka (JP)

(73) Assignee: SHARP KABUSHIKI KAISHA, Osaka-shi, Osaka (JP)

(21) Appl. No.: 13/993,677

(22) PCT Filed: Dec. 14, 2011
(86) PCT No.: PCT/JP2011/078861

§ 371 Date: Jun. 12, 2013

(30) Foreign Application Priority Data
Dec. 21, 2010 (JP) 2010-284504

(51) Int. Cl. H01L 51/00

(52) U.S. Cl. CPC H01L 51/0008
USPC 438/46; 118/715; 118/729; 438/99

(57) ABSTRACT

A vapor deposition device (50) in accordance with the present invention includes: a vapor deposition source (80) which has a plurality of injection holes (81) from which vapor deposition particles are to be injected towards a film formation substrate (60); a plurality of pipes (83a and 83b); a vapor deposition source crucible (82) for supplying the vapor deposition particles to the vapor deposition source (80); and moving means for moving the film formation substrate (60) relative to the vapor deposition source (80). The pipes (83a and 83b) are connected to first and second sides of the vapor deposition source (80) on one end side and the other end side, respectively, of a line of the injection holes (81).

### TECHNICAL FIELD

The present invention relates to (i) a vapor deposition device (vapor deposition apparatus) and (ii) a vapor deposition method each employing a vacuum deposition method, and (iii) a method for producing (manufacturing) an organic electroluminescent display device including the vapor deposition device and employing the vapor deposition method.

### BACKGROUND ART

Recent years have witnessed practical use of a flat-panel display in various products and fields. This has led to a demand for a flat-panel display that is larger in size, achieves higher image quality, and consumes less power.

Under such circumstances, great attention has been drawn to an organic EL display device that (i) includes an organic electroluminescence (hereinafter abbreviated to “EL”) element which uses EL of an organic material and that (ii) is an all-solid-state flat-panel display which is excellent in, for example, low-voltage driving, high-speed response, self-emitting.

An organic EL display device includes, for example, (i) a substrate made up of members such as a glass substrate and TFTs (thin film transistors) provided to the glass substrate and (ii) organic EL elements provided on the substrate and connected to the TFTs.

An organic EL element is a light-emitting element capable of high-luminance light emission based on low-voltage direct-current driving, and includes in its structure a first electrode, an organic EL layer, and a second electrode stacked on top of one another in that order, the first electrode being connected to a TFT. The organic EL layer between the first electrode and the second electrode is an organic layer including a stack of layers such as a hole injection layer, a hole transfer layer, an electron blocking layer, a luminescent layer, a hole blocking layer, an electron transfer layer, and an electron injection layer.

For example, a full-color organic EL display device typically includes, as sub-pixels aligned on a substrate, organic EL elements including luminescent layers of red (R), green (G), and blue (B). The full-color organic EL display device carries out a color image display by, with use of TFTs, selectively causing the organic EL elements to each emit light with a desired luminance.

In order to produce an organic EL display device, it is therefore necessary to form, for each organic EL element, a luminescent layer of a predetermined pattern made of an organic luminescent material which emits light of the colors. A layer that is not required to be patterned in shapes for respective organic EL elements is formed collectively in an entire pixel region constituted by the organic EL elements.

Such formation of a luminescent layer of a predetermined pattern is performed by a method such as (i) a vacuum vapor deposition method, (ii) an inkjet method, and (iii) a laser transfer method. The production of, for example, a low-molecular organic EL display (OLED) often uses a vacuum vapor deposition method (e.g. Patent Literatures 1 and 2).

The vacuum vapor deposition method uses a mask (also called a vapor deposition mask or a shadow mask) provided with openings of a predetermined pattern. The mask is fixed in close contact with a vapor-deposited surface of a substrate which vapor-deposited surface faces a vapor deposition source. Then, vapor deposition particles (film formation material) are injected from the vapor deposition source so as to be deposited on the vapor-deposited surface through openings of the mask. This forms a thin film of a predetermined pattern. The vapor deposition is carried out for each color of a luminescent layer. This is called “selective vapor deposition”.

The following will discuss, with reference to FIGS. 12 and 13, a configuration of a conventional vapor deposition device which employs a vacuum deposition method.

FIG. 12 is a side view schematically illustrating a configuration of a conventional vapor deposition device 250. FIG. 13 is a perspective view schematically illustrating configurations of a vapor deposition source 280, a vapor deposition source crucible 282, and a pipe 283 of the vapor deposition device 250.

As shown in FIG. 12, the vapor deposition device 250 is a device to form a film on a film formation substrate 260. The vapor deposition device 250 includes a shadow mask 270, a vapor deposition source 280, a vapor deposition source crucible 282, and a pipe 283. The shadow mask 270 and the vapor deposition source 280 are provided in a vacuum chamber 290. The vapor deposition source crucible 282 is secured to a support (not illustrated).

The vapor deposition source 280 has a plurality of injection holes (nozzles) 281 from which vapor deposition particles are injected. The injection holes 281 are arranged in a line as shown in FIG. 13.

The vapor deposition source crucible 282 contains a vapor deposition material which is in solid or liquid form. The vapor deposition material is heated in the vapor deposition source crucible 282 so as to be gaseous vapor deposition particles and supplied (introduced) via a pipe 283 to the vapor deposition source 280. The pipe 283 is connected to the vapor deposition source 280 at an end (supply-side end) where one end of the line of the injection holes 281 is located. The vapor deposition particles thus supplied to the vapor deposition source 280 are injected from the injection holes 281. Note that the pipe 283 is heated to such a temperature that the vapor deposition particles do not adhere to the pipe 283.

The film formation substrate 260 and the vapor deposition source 280 are arranged such that a vapor-deposited surface of the film formation substrate 260 faces the vapor deposition source 280. The shadow mask 270, which has an opening corresponding to a pattern of a vapor deposition region, is attached tightly to the vapor deposited-surface of the film formation substrate 260 so that no vapor deposition particles adhere to a region other than the intended vapor deposition region.

According to the configuration, while the vapor deposition particles are injected from the injection holes 281, the film formation substrate 260 and the shadow mask 270 are moved (scanned) relative to the vapor deposition source 280. This forms a predetermined pattern on the film formation substrate 260.

### CITATION LIST

### Patent Literatures

Patent Literature 1

Japanese Patent Application Publication, Tokukaihei, No. 8-227276 A (Publication Date: Sep. 3, 1996)

Patent Literature 2

Japanese Patent Application Publication, Tokukai, No. 2000-188179 A (Publication Date: Jul. 4, 2000)

### SUMMARY OF INVENTION

### Technical Problem

However, the foregoing conventional techniques may cause nonuniformity in distribution of film thickness of a vapor-deposited film.

FIG. 14 is a graph illustrating a relationship between (i) positions on the film formation substrate 260 along a direction in which the injection holes 281 are arranged and (ii) distribution (thickness) of vapor deposition particles. It is assumed in the graph that (i) a position facing a supply-side end of the vapor deposition source 280 is a position A and (ii) a position facing the other end opposite to the supply-side end of the vapor deposition source 280 is a position B.

In the vapor deposition source 280, vapor deposition particles are influenced by pressure difference, internal shapes, and conductance, etc. in supply paths and injection holes. Therefore, different amounts of vapor deposition particles are injected from the injection holes 281. Specifically, since vapor deposition particles are injected sequentially from an injection hole 281 that is close to the supply-side end, density of the vapor deposition particles decreases with increasing distance from the supply-side end. This results in a pressure difference inside the vapor deposition source 280. Therefore, the amount of vapor deposition particles injected from the injection holes 281 decreases with increasing distance from the supply-side end of the vapor deposition source 280. As a result, a vapor-deposited film on the film formation substrate 260, which film is composed of vapor deposition particles injected from various injection holes 281, also includes different amounts of vapor deposition particles depending on the positions on a surface of the substrate (see FIG. 14). This causes nonuniformity in film thickness distribution across the surface of the substrate.

In particular, an organic EL element has a light-emitting property that is highly sensitive to the film thickness of a deposited organic film. Therefore, a variation in the film thickness of the organic film across a screen of an organic EL display device leads directly to display unevenness and nonuniform life property. In view of this, it is preferable to uniformly deposit a luminescent layer of the organic EL element as much as possible.

Note that it is also possible to control the amount of vapor deposition particles to be injected from each injection hole by changing an opening size (diameter) of that injection hole. However, such a control requires high accuracy when making injection holes, and thus leads to an increase in production cost for the vapor deposition source. In addition, the distribution of vapor deposition particles changes dynamically. Therefore, it is difficult to cause vapor deposition particles to be injected from the injection holes in equal amounts only by changing the opening sizes of the injection holes.

Another option is to connect the pipe 283, which is for supplying the vapor deposition particles, to the vapor deposition source 280 at the middle of a longitudinal length of the vapor deposition source 280. However, in this case, density of the vapor deposition particles increases from the position A toward an intermediate position between the position A and the position B, and decreases from the intermediate position toward the position B. Therefore, the distribution is still nonuniform.

The present invention has been made in view of the problems above, and an object of the present invention is to provide a vapor deposition device and a vapor deposition method each of which is capable of vapor deposition of vapor deposition particles on a film formation substrate such that a film made of the vapor deposition particles has a uniform thickness.

### Solution to Problem

In order to attain the above object, a vapor deposition device in accordance with the present invention for forming a film on a film formation substrate includes: a vapor deposition source which has a plurality of injection holes from which vapor deposition particles are to be injected towards the film formation substrate, the plurality of injection holes being arranged in one or more lines; a plurality of pipes connected to the vapor deposition source; and vapor deposition particle supplying means for supplying the vapor deposition particles to the vapor deposition source via the plurality of pipes, the plurality of pipes including at least one pipe which is connected to a first side of the vapor deposition source on one end side of the one or more lines of the plurality of injection holes, and the plurality of pipes including at least one pipe which is connected to a second side of the vapor deposition source on the other end side of the one or more lines of the plurality of injection holes.

In order to attain the above object, a vapor deposition method in accordance with the present invention for forming a film on a film formation substrate includes the steps of: (a) while supplying, via a pipe, vapor deposition particles to a vapor deposition source which has a plurality of injection holes arranged in one or more lines, injecting the vapor deposition particles from the plurality of injection holes towards the film formation substrate, the pipe being connected to a first side of the vapor deposition source on one end side of the one or more lines of the plurality of injection holes; and (b) after the step (a), while supplying, via a pipe, the vapor deposition particles to the vapor deposition source, injecting the vapor deposition particles from the plurality of injection holes towards the film formation substrate, the pipe being connected to a second side of the vapor deposition source on the other end side of the one or more lines of the plurality of injection holes.

According to the vapor deposition device and the vapor deposition method, the vapor deposition particles are supplied to the vapor deposition source via a plurality of pipes from the vapor deposition particle supplying means, and injected from the injection holes towards the film formation substrate. In a case where the vapor deposition particles are supplied via a pipe connected to the first side of the vapor deposition source on one end side of the line of the injection holes (referred to as a “first pipe”), the amount of vapor deposition particles to be injected from the injection holes monotonously decreases with increasing distance from the one end. Further, in a case where the vapor deposition particles are supplied via a pipe connected to the second side of the vapor deposition source on the other end side of the line of the injection holes (referred to as a “second pipe”), the amount of the vapor deposition particles to be injected from the injection holes monotonously decreases with increasing distance from the other end. With this, film thickness distribution of vapor deposition particles deposited after being supplied via the first pipe and those deposited after being supplied via the second pipe are symmetrical about the center of the substrate. Accordingly, film thickness distribution which is a combination of these film thickness distributions is more uniform than that obtained in a case where the vapor deposition is carried out without rotating the vapor deposition source. As such, it is possible to provide a vapor deposition device and a vapor deposition method each of which is capable of vapor deposition of vapor deposition particles on a film formation substrate such that a film made of the vapor deposition particles has a uniform thickness.

A method for producing an organic electroluminescent display device of the present invention includes the steps of: (A) forming a first electrode on a TFT substrate; (B) depositing, over the TFT substrate, an organic layer including at least a luminescent layer; (C) depositing a second electrode; and (D) sealing, with a sealing member, an organic electroluminescent element including the organic layer and the second electrode, at least one of the steps (B), (C), and (D) including the steps (a) and (b) of the vapor deposition method mentioned above.

According to the arrangement, it is possible, by a vapor deposition method of the present invention, to form an organic layer or the like having a uniform film thickness. This makes it possible to provide an organic electroluminescent display device which causes less display unevenness.

### Advantageous Effects of Invention

As has been described, a vapor deposition device in accordance with the present invention for forming a film on a film formation substrate includes: a vapor deposition source which has a plurality of injection holes from which vapor deposition particles are to be injected towards the film formation substrate, the plurality of injection holes being arranged in one or more lines; a plurality of pipes connected to the vapor deposition source; vapor deposition particle supplying means for supplying the vapor deposition particles to the vapor deposition source via the plurality of pipes; and moving means for moving the film formation substrate relative to the vapor deposition source, the plurality of pipes including at least one pipe which is connected to a first side of the vapor deposition source on one end side of the one or more lines of the plurality of injection holes, and the plurality of pipes including at least one pipe which is connected to a second side of the vapor deposition source on the other end side of the one or more lines of the plurality of injection holes. Further, a vapor deposition method in accordance with the present invention for forming a film on a film formation substrate includes the steps of: (a) while supplying, via a pipe, vapor deposition particles to a vapor deposition source which has a plurality of injection holes arranged in one or more lines and moving the film formation substrate relative to the vapor deposition source, injecting the vapor deposition particles from the plurality of injection holes towards the film formation substrate, the pipe being connected to a first side of the vapor deposition source on one end side of the one or more lines of the plurality of injection holes; and (b) after the step (a), while supplying, via a pipe, the vapor deposition particles to the vapor deposition source and moving the film formation substrate relative to the vapor deposition source, injecting the vapor deposition particles from the plurality of injection holes towards the film formation substrate, the pipe being connected to a second side of the vapor deposition source on the other end side of the one or more lines of the plurality of injection holes. Therefore, the present invention brings about an effect of providing a vapor deposition device and a vapor deposition method each of which is capable of vapor deposition of vapor deposition particles on a film formation substrate such that a film made of the vapor deposition particles has a uniform film thickness.

### BRIEF DESCRIPTION OF DRAWINGS

FIG. 1 is a side view illustrating a configuration of a vapor deposition device in accordance with an embodiment of the present invention.

FIG. 2 is a perspective view schematically illustrating a configuration of a vapor deposition source provided in the vapor deposition device.

FIG. 3 is a graph illustrating a relationship between (i) positions on a film formation substrate along a direction in which injection holes in a vapor deposition source are arranged and (ii) distribution (thickness) of vapor deposition particles.

FIG. 4 is views showing other examples of a connection of a vapor deposition source and a pipe.

FIG. 5 is a view illustrating a modification example of the vapor deposition device.

FIG. 6 is a cross-sectional view schematically illustrating a configuration of an organic EL display device for carrying out an RGB full-color display.

FIG. 7 is a plan view illustrating configurations of pixels constituting the organic EL display device shown in FIG. 6.

FIG. 8 is a cross-sectional view (taken along the line A-A) of a TFT substrate of the organic EL display device shown in FIG. 7.

FIG. 9 is a flowchart indicating successive steps for producing an organic EL display device in accordance with an embodiment of the present invention.

FIG. 10 is a side view illustrating a configuration of a vapor deposition device in accordance with another embodiment of the present invention.

FIG. 11 is a graph illustrating a relationship between (i) positions on a film formation substrate along a direction in which injection holes in a vapor deposition source are arranged and (ii) distribution (thickness) of vapor deposition particles.

FIG. 12 is a side view schematically illustrating a configuration of a conventional vapor deposition device.

FIG. 13 is a perspective view schematically illustrating a configuration of a vapor deposition source unit of the vapor deposition device shown in FIG. 12.

FIG. 14 is a graph illustrating a relationship between (i) positions on a film formation substrate along a direction in which injection holes in a vapor deposition source are arranged and (ii) distribution (thickness) of vapor deposition particles.

### DESCRIPTION OF EMBODIMENTS

Embodiments of the present invention are described below in detail.

### Embodiment 1

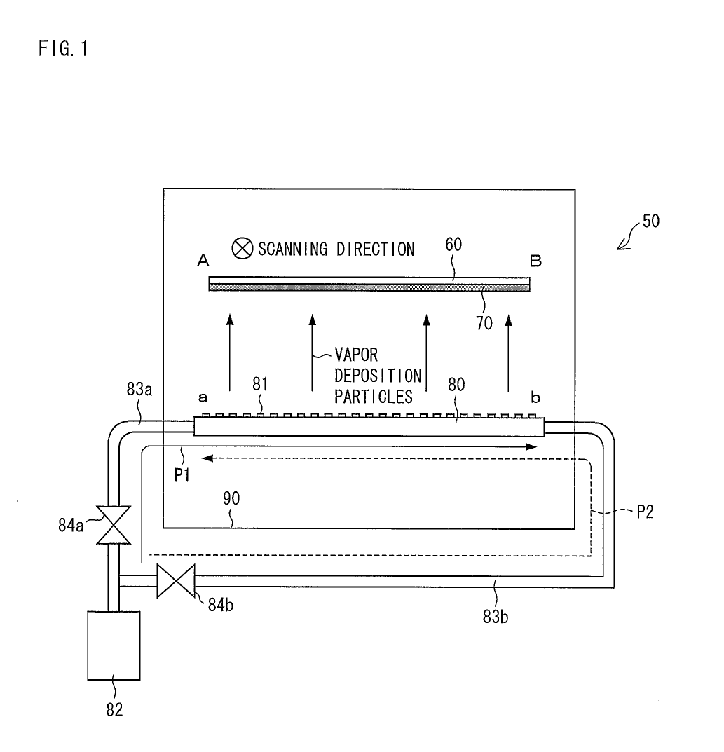

An embodiment of the present invention is described below with reference to FIGS. 1 through 9.

The present embodiment describes, as an example vapor deposition method involving a vapor deposition device of the present embodiment, a method for producing an organic EL display device that (i) is of a bottom emission type, that is, extracts light from a TFT substrate side, and that (ii) carries out an RGB full color display.

The description first deals with the overall configuration of the organic EL display device.

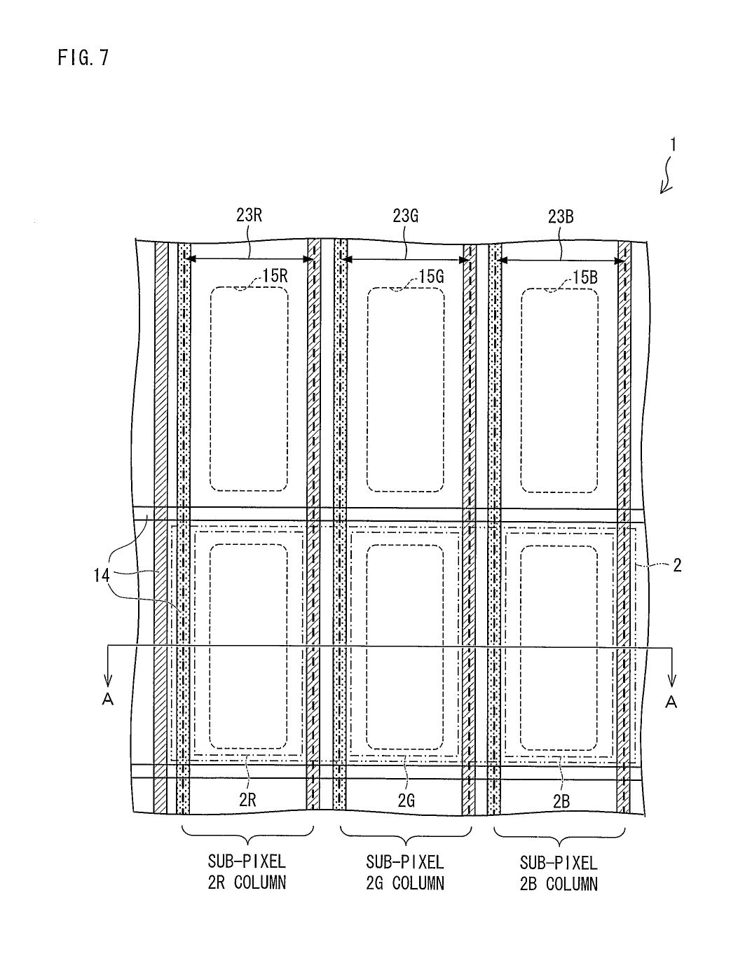

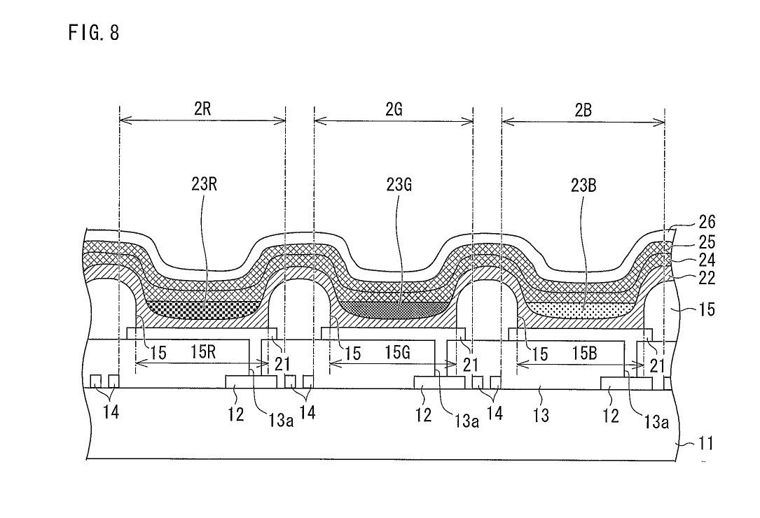

FIG. 6 is a cross-sectional view schematically illustrating a configuration of the organic EL display device that carries out an RGB full color display. FIG. 7 is a plan view illustrating an arrangement of pixels included in the organic EL display device illustrated in FIG. 6. FIG. 8 is a cross-sectional view, taken along the line A-A in FIG. 7, of a TFT substrate included in the organic EL display device illustrated in FIG. 7.

As illustrated in FIG. 6, the organic EL display device 1 produced in the present embodiment includes: a TFT substrate 10 including TFTs 12 (see FIG. 8); organic EL elements 20 provided on the TFT substrate 10 and connected to the TFTs 12; an adhesive layer 30; and a sealing substrate 40 arranged in that order.

The organic EL elements 20, as illustrated in FIG. 6, are contained between the TFT substrate 10 and the sealing substrate 40 by attaching the TFT substrate 10, on which the organic EL elements 20 are provided, to the sealing substrate 40 with use of the adhesive layer 30.

The organic EL display device 1, in which the organic EL elements 20 are contained between the TFT substrate 10 and the sealing substrate 40 as described above, prevents infiltration of oxygen, moisture and the like present outside into the organic EL elements 20.

As illustrated in FIG. 8, the TFT substrate 10 includes, as a supporting substrate, a transparent insulating substrate 11 such as a glass substrate. The insulating substrate 11 is, as illustrated in FIG. 7, provided with a plurality of wires 14 including (i) a plurality of gate lines laid in the horizontal direction and (ii) a plurality of signal lines laid in the vertical direction and intersecting with the gate lines. The gate lines are connected to a gate line driving circuit (not shown in the drawings) that drives the gate lines, whereas the signal lines are connected to a signal line driving circuit (not shown in the drawings) that drives the signal lines.

The organic EL display device 1 is a full-color, active matrix organic EL display device. The organic EL display device 1 includes, on the insulating substrate 11 and in regions defined by the wires 14, sub-pixels 2R, 2G, and 2B arranged in a matrix which include organic EL elements 20 of red (R), green (G), and blue (B), respectively.

In other words, the regions defined by the wires 14 each (i) correspond to a single sub-pixel (dot) and (ii) provide a luminescent region of R, G, or B for each sub-pixel.

A pixel 2 (that is, a single pixel) that includes three sub-pixels: a red sub-pixel 2R transmitting red light; a green sub-pixel 2G transmitting green light; and a blue sub-pixel 2B transmitting blue light.

The sub-pixels 2R, 2G, and 2B include, as luminescent regions of the respective colors which luminescent regions perform light emission of the respective sub-pixels 2R, 2G, and 2B, openings 15R, 15G, and 15B that are covered respectively by stripe-shaped luminescent layers 23R, 23G, and 23B of the respective colors.

The luminescent layers 23R, 23G, and 23B are each formed in a pattern by vapor deposition. The openings 15R, 15G, and 15B are described below in detail.

The sub-pixels 2R, 2G, and 2B include respective TFTs 12 each connected to a first electrode 21 of a corresponding one of the organic EL elements 20. The sub-pixels 2R, 2G, and 2B each have an emission intensity that is determined by scan through the wires 14 and selection of the TFTs 12. As described above, the organic EL display device 1 carries out an image display by selectively causing the organic EL elements 20 to emit, by use of the TFTs 12, light with desired luminance.

The following describes in detail respective configurations of the TFT substrate 10 and each of the organic EL elements 20 both included in the organic EL display device 1.

The description below first deals with the TFT substrate 10.

The TFT substrate 10, as illustrated in FIG. 8, includes on a transparent insulating substrate 11 such as a glass substrate: TFTs 12 (switching elements); an interlayer film 13 (interlayer insulating film planarizing film); wires 14; and an edge cover 15, formed in that order.

The insulating substrate 11 is provided thereon with (i) wires 14 and (ii) TFTs 12 corresponding respectively to the sub-pixels 2R, 2G, and 2B. Since the configuration of a TFT has conventionally been well known, the individual layers of a TFT 12 are not illustrated in the drawings or described herein.

The interlayer film 13 is provided on the insulating substrate 11 throughout the entire region of the insulating substrate 11 to cover the TFTs 12.

There are provided on the interlayer film 13 first electrodes 21 of the organic EL elements 20.

The interlayer film 13 has contact holes 13a for electrically connecting the first electrodes 21 of the organic EL elements 20 to the TFTs 12. This electrically connects the TFTs 12 to the organic EL elements 20 via the contact holes 13a.

The edge cover 15 is an insulating layer for preventing a first electrode 21 and a second electrode 26 of a corresponding organic EL element 20 from short-circuiting with each other due to, for example, (i) a reduced thickness of the organic EL layer in an edge section of the pattern of the first electrode 21 or (ii) an electric field concentration.

The edge cover 15 is so formed on the interlayer film 13 as to cover edge sections of the pattern of the first electrode 21.

The edge cover 15 has openings 15R, 15G, and 15B for the sub-pixels 2R, 2G, and 2B, respectively. The openings 15R, 15G, and 15B of the edge cover 15 define the respective luminescent regions of the sub-pixels 2R, 2G, and 2B.

The sub-pixels 2R, 2G, and 2B are, in other words, isolated from one another by the insulating edge cover 15. The edge cover 15 thus functions as an element isolation film as well.

The description below now deals with each of the organic EL elements 20.

Each of the organic EL elements 20 is a light-emitting element capable of high-luminance light emission based on low-voltage direct-current driving, and includes: a first electrode 21; an organic EL layer; and a second electrode 26, provided on top of one another in that order.

The first electrode 21 is a layer having the function of injecting (supplying) positive holes into the organic EL layer. The first electrode 21 is, as described above, connected to a corresponding TFT 12 via a corresponding contact hole 13a.

The organic EL layer provided between the first electrode 21 and the second electrode 26 includes, as illustrated in FIG. 8: a hole injection layer/hole transfer layer 22; luminescent layers 23R, 23G, and 23B; an electron transfer layer 24; and an electron injection layer 25, formed in that order from the first electrode 21 side.

The above stack order intends to use (i) the first electrode 21 as an anode and (ii) the second electrode 26 as a cathode. The stack order of the organic EL layer is reversed in the case where the first electrode 21 serves as a cathode and the second electrode 26 serves as an anode.

The hole injection layer has the function of increasing efficiency in injecting positive holes into the luminescent layers 23R, 23G, and 23B. The hole transfer layer has the function of increasing efficiency in transferring positive holes to the luminescent layers 23R, 23G, and 23B. The hole injection layer/hole transfer layer 22 is so formed uniformly throughout the entire display region of the TFT substrate 10 as to cover the first electrodes 21 and the edge cover 15.

The present embodiment describes an example case involving, as the hole injection layer and the hole transfer layer, a hole injection layer/hole transfer layer 22 that integrally combines a hole injection layer with a hole transfer layer as described above. The present embodiment is, however, not limited to such an arrangement: The hole injection layer and the hole transfer layer may be provided as separate layers independent of each other.

There are provided on the hole injection layer/hole transfer layer 22 the luminescent layers 23R, 23G, and 23B so formed in correspondence with the respective sub-pixels 2R, 2G, and 2B as to cover the respective openings 15R, 15G, and 15B of the edge cover 15.

The luminescent layers 23R, 23G, and 23B are each a layer that has the function of emitting light by recombining (i) holes (positive holes) injected from the first electrode 21 side with (ii) electrons injected from the second electrode 26 side. The luminescent layers 23R, 23G, and 23B are each made of a material with high luminous efficiency, such as a low-molecular fluorescent dye and a metal complex.

The electron transfer layer 24 is a layer that has the function of increasing efficiency in transferring electrons from the second electrode 26 to the luminescent layers 23R, 23G, and 23B. The electron injection layer 25 is a layer that has the function of increasing efficiency in injecting electrons from the second electrode 26 into the luminescent layers 23R, 23G, and 23B.

The electron transfer layer 24 is so provided on the luminescent layers 23R, 23G, and 23B and the hole injection layer/hole transfer layer 22 uniformly throughout the entire display region of the TFT substrate 10 as to cover the luminescent layers 23R, 23G, and 23B and the hole injection layer/hole transfer layer 22. The electron injection layer 25 is so provided on the electron transfer layer 24 uniformly throughout the entire display region of the TFT substrate 10 as to cover the electron transfer layer 24.

The electron transfer layer 24 and the electron injection layer 25 may be provided either (i) as separate layers independent of each other as described above or (ii) integrally with each other. In other words, the organic EL display device 1 may include an electron transfer layer/electron injection layer instead of the electron transfer layer 24 and the electron injection layer 25.

The second electrode 26 is a layer having the function of injecting electrons into the organic EL layer including the above organic layers. The second electrode 26 is so provided on the electron injection layer 25 uniformly throughout the entire display region of the TFT substrate 10 as to cover the electron injection layer 25.

The organic layers other than the luminescent layers 23R, 23G, and 23B are not essential for the organic EL layer, and may thus be included as appropriate in accordance with a required property of the organic EL element 20. The organic EL layer may further include a carrier blocking layer according to need. The organic EL layer can, for example, additionally include, as a carrier blocking layer, a hole blocking layer between the luminescent layers 23R, 23G, and 23B and the electron transfer layer 24 to prevent positive holes from transferring from the luminescent layers 23R, 23G, and 23B to the electron transfer layer 24 and thus to improve luminous efficiency.

The organic EL elements 20 can have, for example, any of the layered structures (1) through (8) below.

(1) first electrode/luminescent layer/second electrode

(2) first electrode/hole transfer layer/luminescent layer/electron transfer layer/second electrode

(3) first electrode/hole transfer layer/luminescent layer/hole blocking layer (carrier blocking layer)/electron transfer layer/second electrode

(4) first electrode/hole transfer layer/luminescent layer/hole blocking layer/electron transfer layer/electron injection layer/second electrode

(5) first electrode/hole injection layer/hole transfer layer/luminescent layer/electron transfer layer/electron injection layer/second electrode

(6) first electrode/hole injection layer/hole transfer layer/luminescent layer/hole blocking layer/electron transfer layer/second electrode

(7) first electrode/hole injection layer/hole transfer layer/luminescent layer/hole blocking layer/electron transfer layer/electron injection layer/second electrode

(8) first electrode/hole injection layer/hole transfer layer/electron blocking layer (carrier blocking layer)/luminescent layer/hole blocking layer/electron transfer layer/electron injection layer/second electrode

As described above, the hole injection layer and the hole transfer layer, for example, may be integrated with each other. The electron transfer layer and the electron injection layer may be integrated with each other.

The structure of the organic EL element 20 is not limited to the above example layered structure, and may be a desired layered structure according to a required property of the organic EL element 20 as described above.

The description below deals with a method for producing the organic EL display device 1.

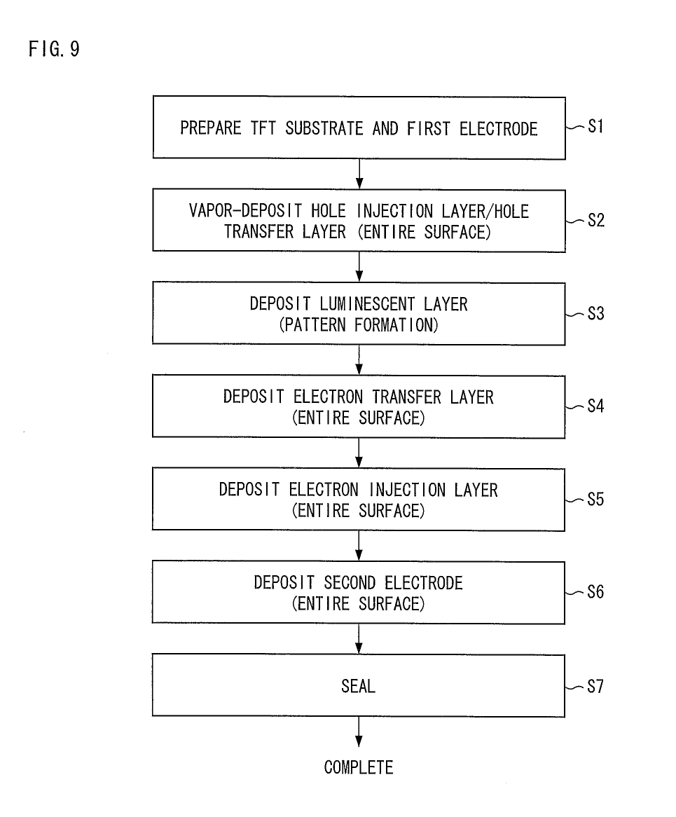

FIG. 9 is a flowchart indicating successive steps for producing the organic EL display device 1.

As illustrated in FIG. 9, the method of the present embodiment for producing the organic EL display device 1 includes steps such as a TFT substrate and first electrode preparing step (S1), a hole injection layer/hole transfer layer vapor deposition step (S2), a luminescent layer vapor deposition step (S3), an electron transfer layer vapor deposition step (S4), an electron injection layer vapor deposition step (S5), a second electrode vapor deposition step (S6), and a sealing step (S7).

The following describes, with reference to the flowchart illustrated in FIG. 9, the individual steps described above with reference to FIGS. 6 and 8.

Note however, that the dimensions, materials, shapes and the like of the respective constituent elements described in the present embodiment merely serve as an embodiment, and that the scope of the present invention should not be construed limitedly on the grounds of such aspects of the constituent elements.

The stack order described in the present embodiment, as mentioned above, intends to use (i) the first electrode 21 as an anode and (ii) the second electrode 26 as a cathode. In the converse case where the first electrode 21 serves as a cathode and the second electrode 26 serves as an anode, the stack order of the organic EL layer is reversed, and the respective materials of the first electrode 21 and the second electrode 26 are switched similarly.

First, as illustrated in FIG. 8, the method of the present embodiment (i) applies a photosensitive resin onto an insulating substrate 11 that is made of a material such as glass and that includes, for example, TFTs 12 and wires 14 each formed by a publicly known technique, and (ii) carries out patterning with respect to the photosensitive resin by photolithography. This forms an interlayer film 13 on the insulating substrate 11.

The insulating substrate 11 is, for example, a glass or plastic substrate having (i) a thickness of 0.7 to 1.1 mm, (ii) a length (longitudinal length) of 400 to 500 mm along a y axis direction, and (iii) a length (lateral length) of 300 to 400 mm along an x axis direction. The insulating substrate 11 of the present embodiment was a glass substrate.

The interlayer film 13 can be made of, for example, an acrylic resin or a polyimide resin. The acrylic resin is, for example, a product in the Optomer series available from JSR Corporation. The polyimide resin is, for example, a product in the Photoneece series available from Toray Industries, Inc. Note that since a typical polyimide resin is not transparent but colored, the interlayer film 13 is more suitably made of a transparency resin such as an acrylic resin in the case where an organic EL display device of the bottom emission type is produced as the organic EL display device 1 as illustrated in FIG. 8.

The interlayer film 13 is simply required to have a film thickness that can compensate for the difference in level created by the TFTs 12. The film thickness is thus not particularly limited. The film thickness was, for example, approximately 2 μm in the present embodiment.

The method of the present embodiment next forms, in the interlayer film 13, contact holes 13a for electrically connecting the first electrodes 21 to the TFTs 12.

The method then forms, as a conductive film (electrode film), a film such as an ITO (indium tin oxide) film by a method such as a sputtering method so that the film has a thickness of 100 nm.

The method next applies a photoresist onto the ITO film, carries out patterning with respect to the photoresist by photolithography, and then carries out etching with respect to the ITO film with use of ferric chloride as an etchant. The method then strips the photoresist with use of a resist exfoliative solution, and further washes the substrate. This forms, on the interlayer film 13, first electrodes 21 in a matrix.

The conductive film material for the first electrode 21 is, for example, (i) a transparent conductive material such as ITO, IZO (indium zinc oxide), and gallium-added zinc oxide (GZO) or (ii) a metal material such as gold (Au), nickel (Ni), and platinum (Pt).

The above conductive film can be formed by, instead of the sputtering method, a method such as a vacuum vapor deposition method, a chemical vapor deposition (CVD) method, a plasma CVD method, and a printing method.

The thickness of the first electrodes 21 is not particularly limited. The first electrodes 21 can have a thickness of, for example, 100 nm as mentioned above.

The method next forms a pattern of an edge cover 15, as with the interlayer film 13, to have a film thickness of, for example, approximately 1 μm. The edge cover 15 can be made of an insulating material similar to that for the interlayer film 13.

The step described above prepares the TFT substrate 10 and the first electrode 21 (S1).

The method of the present embodiment next carries out, with respect to the TFT substrate 10 prepared through the above step, (i) a bake under a reduced pressure for dehydration and (ii) an oxygen plasma treatment for surface washing of the first electrode 21.

The method then carries out vapor deposition of a hole injection layer and a hole transfer layer (in the present embodiment, a hole injection layer/hole transfer layer 22) on the TFT substrate 10 throughout its entire display region with use of a conventional vapor deposition device (S2).

Specifically, the method (i) carries out an alignment adjustment, relative to the TFT substrate 10, of an open mask having an opening corresponding to the entire display region and (ii) closely attaches the open mask to the TFT substrate 10. The method then, while rotating the TFT substrate 10 and the open mask together, carries out, through the opening of the open mask and uniformly throughout the entire display region, vapor deposition of vapor deposition particles scattered from a vapor deposition source.

The above vapor deposition carried out throughout the entire display region refers to vapor deposition carried out unintermittently over sub-pixels having different colors and located adjacent to one another.

The hole injection layer and the hole transfer layer are each made of a material such as (i) benzine, styryl amine, triphenylamine, porphyrin, triazole, imidazole, oxadiazole, polyarylalkane, phenylenediamine, arylamine, oxazole, anthracene, fluorenone, hydrazone, stilbene, triphenylene, azatriphenylene, or a derivative of any of the above, (ii) a polysilane compound, (iii) a vinylcarbazole compound, (iv) and a monomer, an oligomer, or a polymer of a heterocyclic conjugated system or an open chain conjugated system, such as a thiophene compound and an aniline compound.

The hole injection layer and the hole transfer layer may be either integrated with each other as described above or formed as separate layers independent of each other. The hole injection layer and the hole transfer layer each have a film thickness of, for example, 10 to 100 nm.

The present embodiment used, as the hole injection layer and the hole transfer layer, a hole injection layer/hole transfer layer 22 that was made of 4,4′-bis[N-(1-naphthyl)-N-phenylamino]biphenyl(α-NPD) and that had a film thickness of 30 nm.

The method of the present embodiment next carries out a selective application formation (pattern formation) of luminescent layers 23R, 23G, and 23B on the hole injection layer/hole transfer layer 22 in correspondence with respective sub-pixels 2R, 2G, and 2B so that the luminescent layers 23R, 23G, and 23B cover respective openings 15R, 15G, and 15B of the edge cover 15 (S3).

As described above, the luminescent layers 23R, 23G, and 23B are each made of a material with high luminous efficiency, such as a low-molecular fluorescent dye and a metal complex.

The luminescent layers 23R, 23G, and 23B are each made of a material such as (i) anthracene, naphthalene, indene, phenanthrene, pyrene, naphthacene, trip henylene, anthracene, perylene, picene, fluoranthene, acephenanthrylene, pentaphene, pentacene, coronene, butadiene, coumarin, acridine, stilbene, or a derivative of any of the above, (ii) a tris(8-hydroxyquinolinate) aluminum complex, (iii) a bis(benzohydroxyquinolinate)beryllium complex, (iv) a tri(dibenzoylmethyl)phenanthroline europium complex, (v) and ditoluyl vinyl biphenyl.

The luminescent layers 23R, 23G, and 23B each have a film thickness of, for example, 10 to 100 nm.

The vapor deposition method and the vapor deposition device of the present embodiment are each particularly suitably used for a selective application formation (pattern formation) of such luminescent layers 23R, 23G, and 23B.

A description below deals in detail with a selective application formation of the luminescent layers 23R, 23G, and 23B which selective application formation involves the vapor deposition method and the vapor deposition device of the present embodiment.

The method of the present embodiment next carries out, in a manner similar to that described for the above hole injection layer/hole transfer layer vapor deposition step (S2), vapor deposition of an electron transfer layer 24 throughout the entire display region of the TFT substrate 10 so that the electron transfer layer 24 covers the hole injection layer/hole transfer layer 22 and the luminescent layers 23R, 23G, and 23B (S4).

The method then carries out, in a manner similar to that described for the above hole injection layer/hole transfer layer vapor deposition step (S2), vapor deposition of an electron injection layer 25 throughout the entire display region of the TFT substrate 10 so that the electron injection layer 25 covers the electron transfer layer 24 (S5).

The electron transfer layer 24 and the electron injection layer 25 are each made of a material such as a tris(8-hydroxyquinolinate)aluminum complex, an oxadiazole derivative, a triazole derivative, a phenylquinoxaline derivative, or a silole derivative.

Specific examples of the material include (i) Alq(tris(8-hydroxy quinoline)aluminum), anthracene, naphthalene, phenanthrene, pyrene, anthracene, perylene, butadiene, coumarin, acridine, stilbene, 1,10-phenanthroline, and a derivative or metal complex of any of the above, and (ii) LiF.

As mentioned above, the electron transfer layer 24 and the electron injection layer 25 may be either integrated with each other or formed as separate layers independent of each other. The electron transfer layer 24 and the electron injection layer 25 each have a film thickness of, for example, 1 to 100 nm. The respective film thicknesses of the electron transfer layer 24 and the electron injection layer 25 add up to, for example, 20 to 200 nm.

In the present embodiment, (i) the electron transfer layer 24 was made of Alq, whereas the electron injection layer 25 was made of LiF, and (ii) the electron transfer layer 24 had a film thickness of 30 nm, whereas the electron injection layer 25 had a film thickness of 1 nm.

The method of the present embodiment next carries out, in a manner similar to that described for the above hole injection layer/hole transfer layer vapor deposition step (S2), vapor deposition of a second electrode 26 throughout the entire display region of the TFT substrate 10 so that the second electrode 26 covers the electron injection layer 25 (S6).

The second electrode 26 is suitably made of a material (electrode material) such as a metal with a small work function. Examples of such an electrode material include a magnesium alloy (for example, MgAg), an aluminum alloy (for example, AlLi, AlCa, or AlMg) and calcium metal. The second electrode 26 has a thickness of, for example, 50 to 100 nm.

In the present embodiment, the second electrode 26 was made of aluminum and has a film thickness of 50 nm. The operation described above forms, on the TFT substrate 10, organic EL elements each including the organic EL layer, the first electrode 21, and the second electrode 26 described above.

The method of the present embodiment then attached (i) the TFT substrate 10, on which the organic EL elements 20 is provided, to (ii) a sealing substrate 40 with use of an adhesive layer 30 as illustrated in FIG. 6 so that the organic EL elements 20 were contained.

The sealing substrate 40 is, for example, an insulating substrate such as a glass substrate and a plastic substrate and 0.4 to 1.1 mm in thickness. The sealing substrate 40 of the present embodiment was a glass substrate.

The longitudinal and lateral lengths of the sealing substrate 40 may each be adjusted as appropriate in accordance with the size of a target organic EL display device 1. The sealing substrate may be an insulating substrate substantially equal in size to the insulating substrate 11 of the TFT substrate 10, in which case a combination of the sealing substrate 40, the TFT substrate 10, and the organic EL elements 20 contained therebetween is divided in accordance with the size of a target organic EL display device 1.

The method for containing the organic EL elements 20 is not limited to the method described above. Examples of other containing methods include (i) a method that uses a centrally depressed glass substrate as the sealing substrate 40 and that the combination of the sealing substrate 40 and the TFT substrate 10 is sealed along the edge in a frame shape with use of, for example, a sealing resin or fritted glass, and (ii) a method that fills a space between the TFT substrate 10 and the sealing substrate 40 with a resin. The method for producing the organic EL display device 1 does not depend on the above containing method, and can employ any of various containing methods.

The second electrode 26 may be provided thereon with a protective film (not shown) that covers the second electrode 26 and that prevents infiltration of oxygen, moisture and the like present outside into the organic EL elements 20.

The protective film is made of an electrically insulating or conductive material such as silicon nitride and silicon oxide. The protective film has a thickness of, for example, 100 to 1000 nm.

Through the above steps, the organic EL display device 1 is finally produced.

The organic EL display device 1 turns on a TFT 12 upon receipt of a signal through a wire 14, and thus allows (i) positive holes to be injected from the first electrode 21 into the organic EL layer and also (ii) electrons to be injected from the second electrode 26 into the organic EL layer. This causes the positive holes and the electrons to recombine with each other inside the luminescent layers 23R, 23G, and 23B. The positive holes and the electrons thus recombined are emitted in the form of light when becoming inactive.

In the above organic EL display device 1, controlling respective light emission luminances of the sub pixels 2R, 2G, and 2B allows a predetermined image to be displayed.

The following describes an arrangement of a vapor deposition device of the present embodiment.

FIG. 1 is a side view illustrating a configuration of a vapor deposition device 50 in accordance with the present embodiment. The vapor deposition device 50 is configured to form a film on a film formation substrate 60. The vapor deposition device 50 includes a shadow mask 70, a vapor deposition source 80, a vapor deposition source crucible 82, and two pipes 83a and 83b.

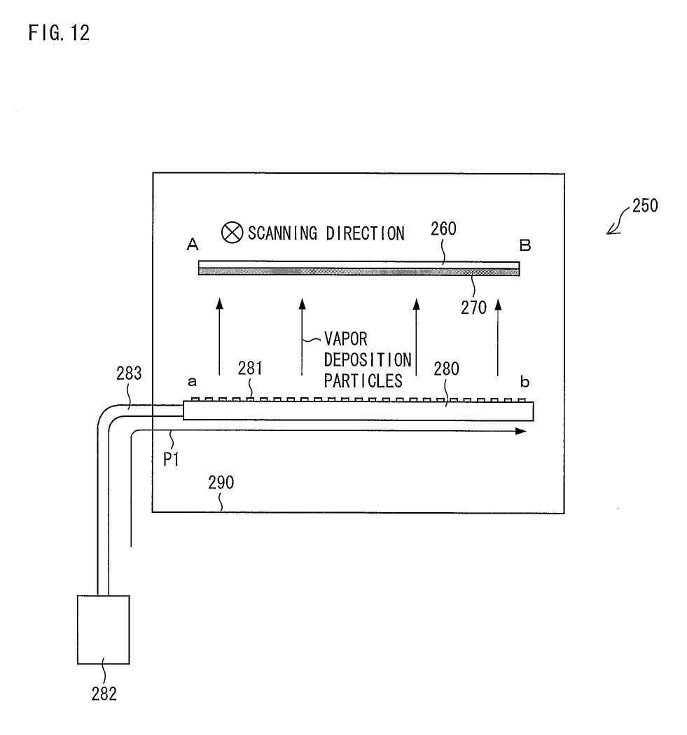

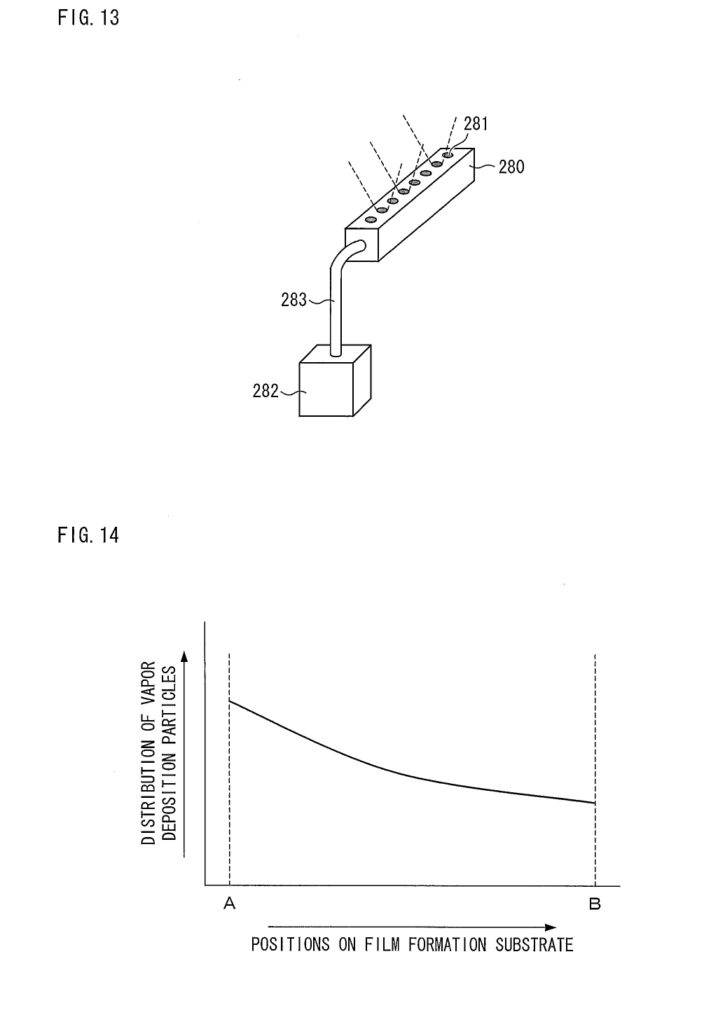

The shadow mask 70 and the vapor deposition source 80 are provided in a vacuum chamber 90. The vapor deposition source crucible 82 is secured to a support (not illustrated). Note that configurations of the film formation substrate 60, the shadow mask 70, and the vapor deposition crucible 82 are identical to those of the film formation substrate 260, the shadow mask 270, and the vapor deposition source crucible 282 as shown in FIG. 12, respectively.

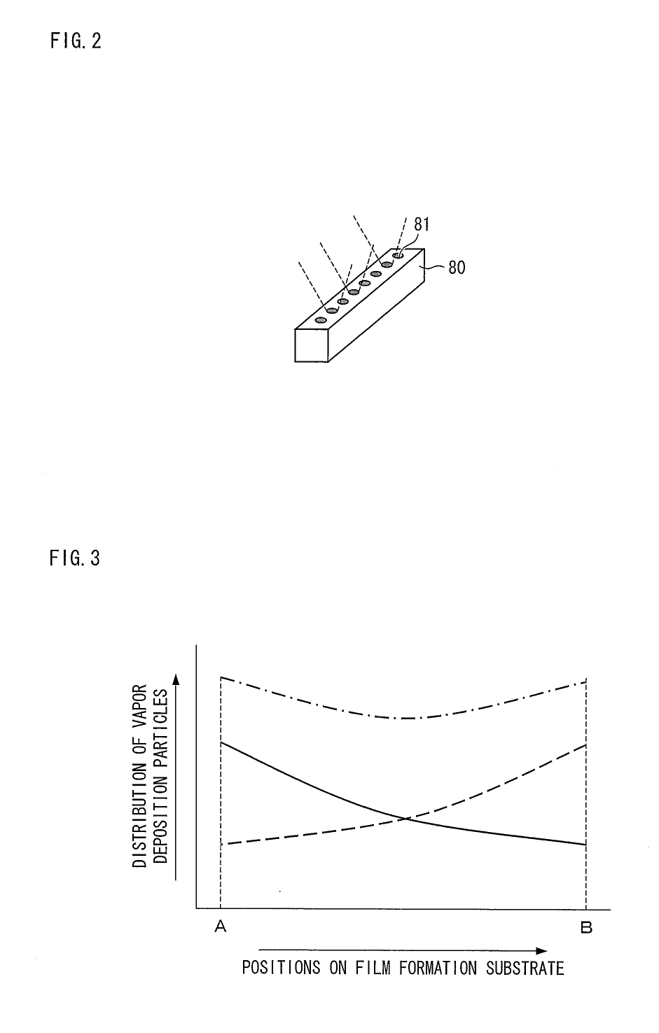

That is, the vapor deposition source 80 has a plurality of injection holes 81 from which vapor deposition particles are to be injected. As shown in FIG. 2, the injection holes 81 are arranged in a line.

The vapor deposition source crucible 82 contains a vapor deposition material which is in solid or liquid form. Further, the vapor deposition source crucible 82 is placed outside the vacuum chamber 90. According to this, the inside of the vacuum chamber 90 does not need to be exposed to the atmosphere every time the vapor deposition material is supplied to the vapor deposition source crucible 82. This allows an improvement in throughput. Further, the vacuum chamber 90 can have spatial room therein. This makes it easy to design the inside of the vacuum chamber 90.

The vapor deposition material is heated inside the vapor deposition source crucible 82 so as to be gaseous vapor deposition particles, and then supplied (introduced) via the pipes 83a and 83b to the vapor deposition source 80. The pipe 83a is connected to a first end surface of the vapor deposition source 80 on one end side of the line of the injection holes 81 (hereinafter a “supply-side end surface a”). The pipe 83b is connected to a second end surface of the vapor deposition source 80 on the other end side of the line of the injection holes 81 (hereinafter a “supply-side end surface b”). The vapor deposition particles thus supplied to the vapor deposition source 80 are injected from the injection holes 81.

The film formation substrate 60 and the vapor deposition source 80 are arranged so that a vapor-deposited surface of the film formation substrate 60 and the vapor deposition source face each other. The shadow mask 70, which has an opening corresponding to a pattern of a vapor deposition region, is fixed tightly to the vapor-deposited surface of the film formation substrate 60 so that the vapor deposition particles are prevented from adhering to a region other than the intended vapor deposition region. While the vapor deposition particles are injected from the injection holes 81, the film formation substrate 60 and the shadow mask 70 are moved (scanned) relative to the vapor deposition source 80 by moving means (not shown). Specifically, while the vapor deposition source 80 is injecting the vapor deposition particles towards the film formation substrate 60, the moving means moves the film formation substrate 60 and the shadow mask 70 back and forth along a direction perpendicular to a direction in which the injection holes 81 are arranged (i.e., in a direction going away from a viewer of FIG. 1 and in a direction coming back toward the viewer of FIG. 1). This forms a predetermined pattern on the film formation substrate 60.

According to the conventional vapor deposition device 250 shown in FIG. 12, the pipe 283 for supplying vapor deposition particles was connected to only one end surface of the vapor deposition source 280 on one end side of the line of the injection holes 281. In contrast, the vapor deposition device 50 in accordance with the present embodiment differs from the conventional vapor deposition device 250 in (i) that the pipe 83a is connected to the first end surface of the vapor deposition source 80 on the one end side of the line of the injection holes 81 and (ii) that the pipe 38b is connected to the second end surface of the vapor deposition source 80 on the other end side of the line of the injection holes 81.

Further, the pipes 83a and 83b are provided with valves 84a and 84b, respectively (supply control means). The valves 84a and 84b control an amount of the vapor deposition particles to be supplied to the vapor deposition source 80 by opening and closing internal paths of the pipes 83a and 83b, respectively. Accordingly, when the valve 84a is opened, the vapor deposition particles pass through an introduction path P1 (indicated by a solid-line arrow). Meanwhile, when the valve 84b is opened, the vapor deposition particles pass through an introduction path P2 (indicated by a dotted-line arrow).

According to the configuration, the introduction paths are changed in accordance with a direction in which the film formation substrate 60 is scanned. Specifically, (i) first, while the valve 84a is opened, the vapor deposition particles are supplied via the pipe 83a to the vapor deposition source 80, and (ii) while the film formation substrate 60 is being scanned away from the viewer of FIG. 1 (such a direction is referred to as a forth direction), the vapor deposition particles are injected via the injection holes 81 towards the film formation substrate 60 (first injecting step). Note that the valve 84b is closed during this step.

After the scanning in the forth direction (i.e., when the film formation substrate 60 reaches a position where it does not face the vapor deposition source 80), the valve 84a is closed to stop the supply of the vapor deposition particles via the pipe 83a. Subsequently, the valve 84b is opened to supply the vapor deposition particles via the pipe 83b to the vapor deposition source 80. Then, the vapor deposition particles are injected from the injection holes 81 towards the film formation substrate 60 while the film formation substrate 60 is being scanned back toward the viewer of FIG. 1 (such a direction is referred to as a back direction) (second injecting step). After the scanning in the back direction, the injection of the vapor deposition particles is stopped.

FIG. 3 is a graph illustrating a relationship between (i) positions on the film formation substrate 60 along a direction in which the injection holes 81 are arranged and (ii) distribution (thickness) of vapor deposition particles. It is assumed in this graph that (i) a position which faces a supply-side end surface of the vapor deposition source 80 in FIG. 1 is a position A and (ii) a position which faces the other end opposite to the supply-side end surface of the vapor deposition source 80 is a position B. A solid line in the graph shows distribution of vapor deposition particles deposited in a case where the film formation substrate 60 is scanned in the forth direction, whereas a dashed line shows distribution of vapor deposition particles deposited in a case where the film formation substrate 60 is scanned in the back direction. Further, a dot-dash line shows distribution of vapor deposition particles after the completion of the scanning in the back and forth directions.

The amount of vapor deposition particles to be injected from the injection holes 81 decreases with increasing distance from the supply-side end surface of the vapor deposition source 80. Therefore, the distribution of the vapor deposition particles which are deposited when the film formation substrate 60 is scanned in the forth direction (i.e., in a case where the vapor deposition particles are supplied to the vapor deposition source 80 via the pipe 83a) gradually decreases from the position A to the position B, as shown by the solid line.

On the other hand, in a case where the film formation substrate 60 is scanned in the back direction, the vapor deposition particles are supplied via the pipe 83b to the vapor deposition source 80. Accordingly, the distribution of the amount of vapor deposition particles to be injected towards the film formation substrate 60 is also reversed. Therefore, as shown by the dashed line, film thickness distribution obtained when the film formation substrate 60 is scanned in the back direction and the film thickness distribution shown by the solid line are symmetrical about an intermediate position between the position A and the position B.

The film thickness distribution after the completion of the scanning of the film formation substrate 60 in the back and forth directions is a sum of the film thickness distribution shown by the solid line and the film thickness distribution shown by the dashed line. Therefore, as shown by the dot-dash line, the film thickness distribution after the completion of the scanning of the film formation substrate 60 in the back and forth directions is uniform in comparison with the film thickness distribution obtained when the scanning is carried out in the forth direction and that obtained when the scanning is carried out in the back direction. That is, by arranging the vapor deposition source 80 such that between when the scanning is carried out in the back direction and when the scanning is carried out in the forth direction, the pipes 83a and 83b via which the vapor deposition particles are supplied to the vapor deposition source 80 are changed by opening and closing the valve 84a and 84b, respectively, it is possible to reduce the influences of pressure difference inside supply paths and the injection holes and thus possible to obtain film thickness distribution which is uniform across the entire deposition region. Specifically, by applying the vapor deposition device 50 to vapor deposition of luminescent layers of organic EL elements, it is possible to produce an organic EL display device which causes less display unevenness.

Further, in a case where the distribution of vapor deposition particles shown by the solid line and that shown by the dashed line in FIG. 3 monotonically increases and decreases (or decreases and increases) respectively in a linear fashion with respect to the positions on the film formation substrate, a combination of such distributions of vapor deposition particles provides more uniform film thickness distribution. That is, the present embodiment provides the highest effect in such a case.

Note that it is unnecessary to change the opening and closing of the valves 84a and 84b every time the scanning direction of the film formation substrate 60 is changed. For example, the opening and closing of the valves 84a and 84b can be changed such that (i) the film formation substrate 60 is scanned in the back and forth directions three times in a state in which the valve 84b is closed and the valve 84a is opened, and then (ii) the film formation substrate 60 is scanned in the back and forth directions three times in a state in which the valve 84a is closed and the valve 84b is opened. The opening and closing of the valves 84a and 84b is changed, after the film formation substrate 60 has passed over the vapor deposition source 80, while the film formation substrate 60 is in such a position that the vapor deposition particles do not reach the film formation substrate 60.

Note that, since other various mechanisms are arranged in the vacuum chamber 90, it is difficult to cause the pipes 83a and 83b to be identical. Therefore, when the valves 84a and 84b are opened, the vapor deposition particles to be supplied from each of the pipes 83a and 83b to the vapor deposition source 80 change in amount due to a subtle difference in shape and/or conductance between the pipes 83a and 83b, and a pressure distribution in the vapor deposition source 80 is also complicated. This makes it difficult to uniform a film thickness distribution. Therefore, it is preferable that the valves 84a and 84b be controlled not to be opened simultaneously. However, if an influence of the pipes 83a and 83b is subtle, the pipes 83a and 84b can be opened simultaneously.

According to the vapor deposition device as described above, the pipes 83a and 83b are connected to the first and second end surfaces of the vapor deposition source 80 on one end side and the other end side, respectively, of the line of the injection holes 81. However, where to connect the pipes 83a and 83b is not limited to this.

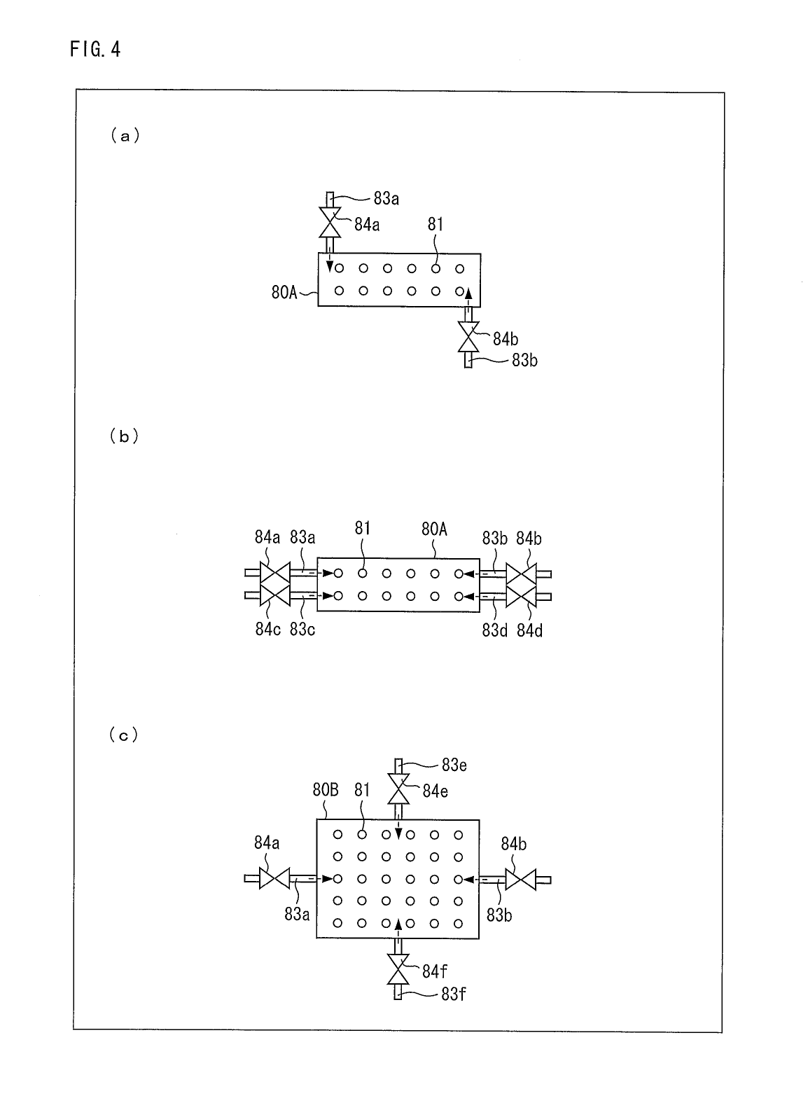

For example, pipes 83a and 83b can each be connected to a longer side surface of a vapor deposition source 80A in a vicinity of an end of a line of injection holes 81 (see (a) of FIG. 4).

Further, according to the vapor deposition device as described above, two paths are provided via which the vapor deposition particles are supplied to the vapor deposition source 80. Alternatively three or more such paths may be provided. For example, the vapor deposition source 80A having a plurality of lines of injection holes 81 is preferably configured such that a plurality of pipes are connected to end surfaces of the vapor deposition source 80A (see (b) of FIG. 4). In (b) of FIG. 4, two pipes 83a and 83c are connected to a first end surface of the vapor deposition source 80A on one end side of each of lines of the injection holes 81. Two pipes 83b and 83d are connected to a second end surface of the vapor deposition source 80A on the other end side of each of the lines of the injection holes 81. This makes it possible to prevent nonuniformity of an amount of vapor deposition particles to be injected for each line of the injection holes 81.

In this case, opening of respective valves 84a and 84c of pipes 83a and 83c and opening of respective valves 83b and 83d of pipes 84b and 84d are changed alternately in accordance with the change in direction in which the film formation substrate 60 is scanned. For example, first, in a state in which the respective valves 84a and 84c of the pipes 83a and 83c are opened and the respective valves 84b and 84d of the pipes 83b and 83d are closed, while the film formation substrate 60 is being scanned in the forth direction, the vapor deposition particles are supplied to the vapor deposition source 80 via the pipes 83a and 83c, and the vapor deposition particles are injected via the injection holes 81 towards the film formation substrate 60. Subsequently, in a state in which the valves 84a and 84c are closed and the valves 84b and 84d are opened, while the film formation substrate 60 is being scanned in the back direction, the vapor deposition particles are supplied to the vapor deposition source 80 via the pipes 83b and 83d, and the vapor deposition particles are injected via the injection holes 81 towards the film formation substrate 60.

Further, according to the vapor deposition device as described above, the pipes are connected to the first and second end surfaces of the vapor deposition source on one end side and the other end side, respectively, of the line of the injection holes. However, where to connect the pipes is not limited to this. As shown in (c) of FIG. 4, in a case where a vapor deposition source 80B includes injection holes provided in a matrix pattern, pipes can be connected to respective four sides of the vapor deposition source 80B.

Specifically, according to the vapor deposition source 80B shown in (c) of FIG. 4, pipes 83a and 83b are connected to respective first and second sides of the vapor deposition source 80b on one end side and the other end side, respectively, of each of lines of the injection holes 81, and pipes 83e and 83f are connected to respective third and fourth sides of the vapor deposition source 80b on one end side and the other end side, respectively, of each of rows of the injection holes 81. This makes it possible to uniform a film thickness distribution in a row direction of the injection holes 81.

In this case, the respective valves 84a, 84b, 84e, and 84f of the pipes 83a, 83b, 83e, and 83f can be opened sequentially in accordance with the change in direction in which the film formation substrate 60 is scanned. Alternatively, all the valves 84a, 84b, 84e and 84f can be opened simultaneously.

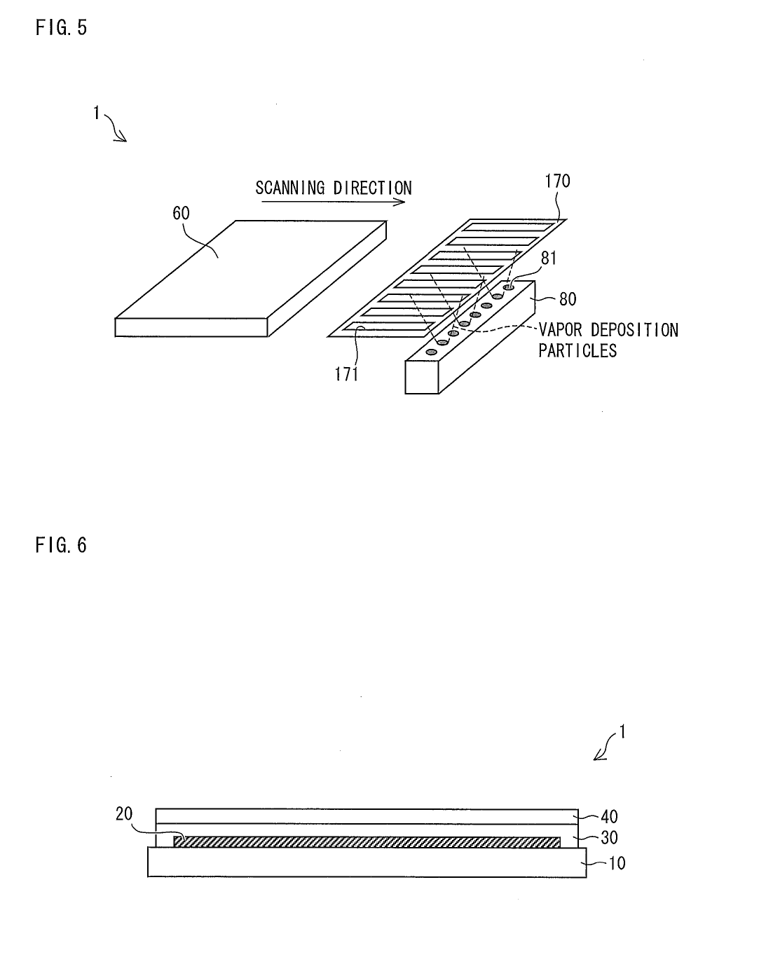

In the present embodiment, the film formation substrate and the shadow mask are in close contact with each other; however, vapor deposition can be carried out in a state where there is a gap between the film formation substrate and the shadow mask. Moreover, although the shadow mask of the present embodiment covers the entire surface of the film formation substrate, this does not imply any limitation. For example, as shown in FIG. 5, a shadow mask 170 can be used which has a smaller area than the vapor deposition region of the film formation substrate 60.

In this case, vapor deposition is carried out in the following manner. The relative positions of the shadow mask 170 and the vapor deposition source are fixed, and the shadow mask 170 and the vapor deposition source 80 are positioned so that the shadow mask 170 faces the film formation substrate with a certain gap between the shadow mask 170 and the film formation substrate. Then, the film formation substrate 60 is moved relative to the shadow mask 170 and the vapor deposition source 80, whereby vapor deposition particles are consecutively deposited through openings 171 in the shadow mask 170 onto a vapor deposition region of the film formation substrate 60.

### Embodiment 2

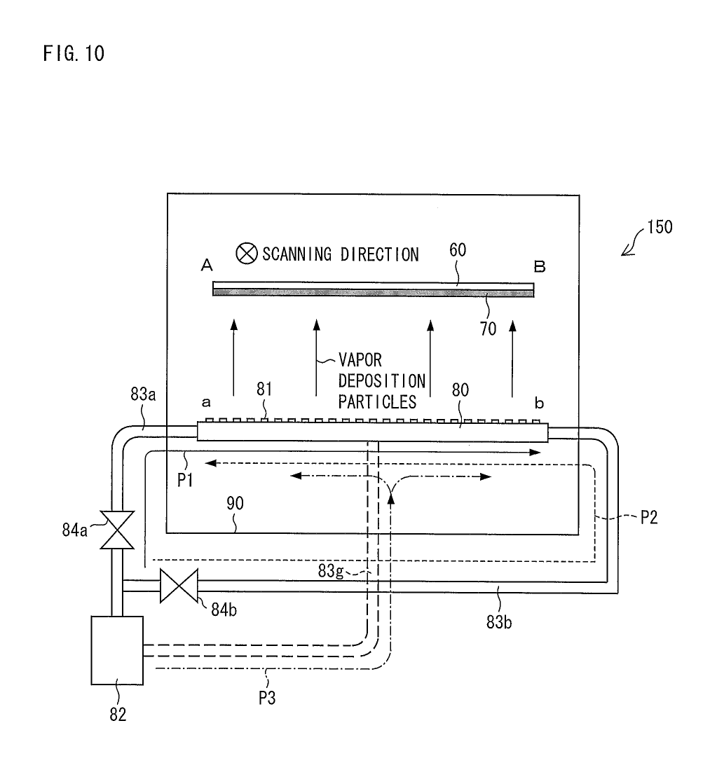

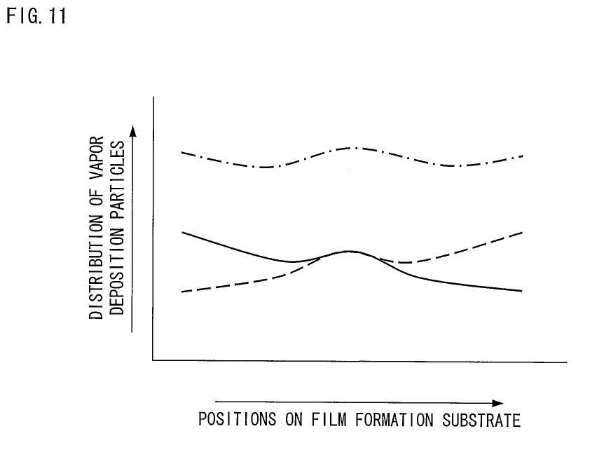

The following description will discuss, with reference to FIGS. 10 and 11, another embodiment of the present invention. According to Embodiment 1, in the distribution of the vapor deposition particles which distribution is indicated by the dashed-dotted line in FIG. 3, a film thickness at the intermediate position between the position A and the position B is smaller than that at the other positions on the film formation substrate. Therefore, the present embodiment describes a configuration which allows insufficiency of the film thickness occurring around the intermediate position between the position A and the position B to be solved by further providing an auxiliary pipe. Note that, for convenience of description, members having the same functions as those described in Embodiment 1 use the same reference numbers and their descriptions are omitted.

FIG. 10 is a side view showing a configuration of a vapor deposition device 150 in accordance with the present embodiment. The vapor deposition device 150 is obtained by causing the vapor deposition device 50 shown in FIG. 1 to further include an auxiliary pipe 83g. The auxiliary pipe 83g is connected to a vapor deposition source 80 in an intermediate part of an arrangement of injection holes 81. This causes a vapor deposition source crucible 82 to supply vapor deposition particles to the vapor deposition source 80 via pipes 83a and 83b, and the auxiliary pipe 83g. That is, the vapor deposition particles are supplied to the vapor deposition source 80 via not only introduction paths P1 and P2 but also an introduction path P3 (indicated by a dashed-dotted line).

Note that no valve is provided to the auxiliary pipe 83g. This means that the vapor deposition particles are supplied to the vapor deposition source via the auxiliary pipe 83g regardless of a direction in which a film formation substrate 60 is scanned. Further, vapor deposition steps are identical to those described in Embodiment 1. This enables the vapor deposition device 150 of the present embodiment to bring about an effect identical to that brought about by the vapor deposition device 50 in accordance with Embodiment 1.

Further, according to the present embodiment, the vapor deposition device 150 which is provided with the auxiliary pipe 83g makes it possible to further uniform a film thickness distribution of vapor deposition particles. This is described with reference to FIG. 11.

FIG. 11 is a graph illustrating a relationship between (i) positions on the film formation substrate 60 along a direction in which the injection holes 81 are arranged and (ii) distribution (thickness) of vapor deposition particles. A solid line in the graph shows distribution of vapor deposition particles deposited in a case where the film formation substrate 60 is scanned in the forth direction, whereas a dashed line shows distribution of vapor deposition particles deposited in a case where the film formation substrate 60 is scanned in the back direction. Further, a dot-dash line shows distribution of vapor deposition particles after the completion of the scanning in the back and forth directions.

Since the vapor deposition particles which are supplied via the introduction path P3 are deposited around the intermediate position between the position A and the position B of the film formation substrate 60, in comparison with the graph of FIG. 3, the graph of FIG. 11 shows that the film thickness obtained around the intermediate position has a protruding shape in any of the distributions indicated by the solid line, the dotted line, and the dashed-dotted line, respectively. According to this, the present embodiment allows a film thickness distribution to be more uniform than the film thickness distribution of Embodiment 1.

Note that a plurality of auxiliary pipes can be provided. In this case, the plurality of auxiliary pipes are connected to a part of a vapor deposition source other than sides of the vapor deposition source on one end side and the other end side, respectively, of each line of the injection holes. Further, the auxiliary pipe 83g can be provided with a valve.

[Additional Matter]

In the foregoing embodiments, a line-type vapor deposition source on which injection holes are arranged in a line is employed. Note however, that a planar vapor deposition source on which there is a plurality of lines of injection holes can also be employed. In this case, pipes are each connected to end surfaces of the vapor deposition source on one end side and the other end side, respectively, of each of the plurality of lines of the injection holes. Further, in a case where an injection surface of a vapor deposition source is sufficiently large and a film formation substrate is relatively small, vapor deposition can be carried out without moving the film formation substrate relative to the vapor deposition source.

Furthermore, although the foregoing embodiments deal with an arrangement in which the direction in which the injection holes are arranged is perpendicular to the direction in which the film formation substrate is to be scanned, the direction in which the injection holes are arranged can deviate to some degree from the direction perpendicular to the direction in which the film formation substrate is to be scanned.

Furthermore, although the foregoing embodiments deal with an arrangement in which each of the injection holes has a point shape, this does not imply any limitation. The injection holes can be, for example, a slit-like opening extending along the direction in which the injection holes are arranged.

Further, the present invention is also applicable to a close-contact-scanning vapor deposition method by which to carry out vapor deposition by sliding a film formation substrate while keeping the film formation substrate and a shadow mask in close contact to each other. Furthermore, the present invention is also applicable to a case where, as shown in S2 and S4 through S6 of FIG. 9, vapor deposition is carried out with respect to the entire surface of the film formation substrate without using a shadow mask in which an opening pattern is formed for each sub-pixel.

Moreover, the present invention is applicable not only to vapor deposition of organic films but also to vapor deposition of second electrodes and sealing films. Note however that, since unevenness in film thickness of an organic film has a larger impact on the properties of an organic EL display device, the present invention is more effective for vapor deposition of the organic film.

On the other hand, unevenness in film thickness of a second electrode leads to unevenness in electric resistance, whereas unevenness in the sealing film leads to unevenness in moisture permeability and oxygen permeability. Provided that the influences of such unevenness on the properties of an organic EL element are minor, the present invention can be applied only to vapor deposition of organic films so that the structure of a vapor deposition device is simple and thus no increase occurs in cost of equipment.

<Main Points of the Invention>

As has been described, a vapor deposition device in accordance with the embodiments of the present invention for forming a film on a film formation substrate includes: a vapor deposition source which has a plurality of injection holes from which vapor deposition particles are to be injected towards the film formation substrate, the plurality of injection holes being arranged in one or more lines; a plurality of pipes connected to the vapor deposition source; and vapor deposition particle supplying means for supplying the vapor deposition particles to the vapor deposition source via the plurality of pipes, the plurality of pipes including at least one pipe which is connected to a first side of the vapor deposition source on one end side of the one or more lines of the plurality of injection holes, and the plurality of pipes including at least one pipe which is connected to a second side of the vapor deposition source on the other end side of the one or more lines of the plurality of injection holes.

As has been described, a vapor deposition method in accordance with the embodiments of the present invention for forming a film on a film formation substrate includes the steps of: (a) while supplying, via a pipe, vapor deposition particles to a vapor deposition source which has a plurality of injection holes arranged in one or more lines, injecting the vapor deposition particles from the plurality of injection holes towards the film formation substrate, the pipe being connected to a first side of the vapor deposition source on one end side of the one or more lines of the plurality of injection holes; and (b) after the step (a), while supplying, via a pipe, the vapor deposition particles to the vapor deposition source, injecting the vapor deposition particles from the plurality of injection holes towards the film formation substrate, the pipe being connected to a second side of the vapor deposition source on the other end side of the one or more lines of the plurality of injection holes.

According to the vapor deposition device and the vapor deposition method, the vapor deposition particles are supplied to the vapor deposition source via a plurality of pipes from the vapor deposition particle supplying means, and injected from the injection holes towards the film formation substrate. In a case where the vapor deposition particles are supplied via a pipe connected to the first side of the vapor deposition source on one end side of the line of the injection holes (referred to as a “first pipe”), the amount of vapor deposition particles to be injected from the injection holes monotonously decreases with increasing distance from the one end. Further, in a case where the vapor deposition particles are supplied via a pipe connected to the second side of the vapor deposition source on the other end side of the line of the injection holes (referred to as a “second pipe”), the amount of the vapor deposition particles to be injected from the injection holes monotonously decreases with increasing distance from the other end. With this, film thickness distribution of vapor deposition particles deposited after being supplied via the first pipe and those deposited after being supplied via the second pipe are symmetrical about the center of the substrate. Accordingly, film thickness distribution which is a combination of these film thickness distributions is more uniform than that obtained in a case where the vapor deposition is carried out without rotating the vapor deposition source. As such, it is possible to provide a vapor deposition device and a vapor deposition method each of which is capable of vapor deposition of vapor deposition particles on a film formation substrate such that a film made of the vapor deposition particles has a uniform thickness.

The vapor deposition device in accordance with the embodiments of the present invention is preferably configured such that each of the plurality of pipes is provided with supply control means for controlling an amount of the vapor deposition particles to be supplied to the vapor deposition source.

According to the configuration, the supply control means can turn on/off the supply of the vapor deposition particles via each of the plurality of pipes. According to this, in a case where the pipes via which the vapor deposition particles are to be supplied are changed in accordance with a change in direction in which the film formation substrate is moved relative to the vapor deposition source, the vapor deposition particles can be deposited so as to have a more uniform film thickness.

The vapor deposition device in accordance with the embodiments of the present invention is preferably configured such that the vapor deposition particles are supplied to the vapor deposition source via any one of the plurality of pipes so as to be injected.

In a case where the vapor deposition particles are supplied from the plurality of pipes simultaneously, a pressure distribution in the vapor deposition source is complicated due to influences such as a difference in shape and/or conductance among the plurality of pipes. However, according to the configuration, the vapor deposition particles are supplied via any one of the plurality of pipes. Therefore, a more uniform film thickness can be obtained.

The vapor deposition device in accordance with the embodiments of the present invention is preferably configured such that (i) the at least one pipe connected to the first side of the vapor deposition source on the one end side of the one or more lines of the plurality of injection holes and (ii) the at least one pipe connected to the second side of the vapor deposition source on the other end side of the one or more lines of the plurality of injection holes each include a plurality of pipes.

According to the configuration, particularly in a case where the injection holes are arranged in a plurality of lines, it is also possible to prevent nonuniformity of an amount of the vapor deposition particles to be injected for each of the plurality of lines of the injection holes.

The vapor deposition device in accordance with the embodiments of the present invention is preferably configured such that: the plurality of injection holes are arranged in a matrix pattern; the plurality of pipes include at least one pipe which is connected to a third side of the vapor deposition source on one end side of one or more rows of the plurality of injection holes; and the plurality of pipes include at least one pipe which is connected to a fourth side of the vapor deposition source on the other end side of the one or more rows of the plurality of injection holes.

According to the configuration, it is possible to uniform a film thickness distribution in a row direction.

The vapor deposition device in accordance with the embodiments of the present invention is preferably configured to further include: an auxiliary pipe in addition to the plurality of pipes, the vapor deposition particles supplying means supplying the vapor deposition particles to the vapor deposition source via the plurality of pipes and the auxiliary pipe, and the auxiliary pipe being connected to a part of the vapor deposition source other than the first and second sides of the vapor deposition source on the one end side and the other end side, respectively, of the one or more lines of the plurality of injection holes.

The vapor deposition device in accordance with the embodiments of the present invention is preferably configured such that the auxiliary pipe is connected to the vapor deposition source in an intermediate part of the arrangement of the plurality of injection holes.

According to the configuration, it is possible to compensate, with the vapor deposition particles supplied via the auxiliary pipe, a part of a film thickness distribution in which part a film thickness is small, the film thickness distribution being obtained by supplying the vapor deposition particles from the first and second sides of the vapor deposition source on respective both end sides of the line of the injection holes. This makes it possible to obtain a more uniform distribution of thickness.

The vapor deposition device in accordance with the embodiments of the present invention is preferably configured to further include: moving means for moving the film formation substrate relative to the vapor deposition source.

According to the configuration, it is possible to easily form a film on a film formation substrate which is larger in vapor deposition region than an injection surface of the vapor deposition source.

The vapor deposition device in accordance with the embodiments of the present invention is preferably configured such that a direction in which the plurality of injection holes are arranged is perpendicular to a direction in which the film formation substrate is moved relative to the vapor deposition source.

According to the configuration, the vapor deposition source and the film formation substrate can be easily aligned.

A method for producing an organic electroluminescent display device in accordance with the embodiments of the present invention includes the steps of: (A) forming a first electrode on a TFT substrate; (B) depositing, over the TFT substrate, an organic layer including at least a luminescent layer; (C) depositing a second electrode; and (D) sealing, with a sealing member, an organic electroluminescent element including the organic layer and the second electrode, at least one of the steps (B), (C), and (D) including the steps (a) and (b) of the vapor deposition method mentioned above.

According to the arrangement, it is possible, by a vapor deposition method in accordance with the embodiments of the present invention, to form an organic layer or the like having a uniform film thickness. This makes it possible to provide an organic electroluminescent display device which causes less display unevenness.

The present invention is not limited to the descriptions of the respective embodiments, but may be altered within the scope of the claims. An embodiment derived from a proper combination of technical means disclosed in different embodiments is also encompassed in the technical scope of the invention.

### INDUSTRIAL APPLICABILITY

The present invention is applicable not only to deposition of vapor deposition particles during production of an organic EL display device but also to deposition of vapor deposition particles with respect to any film formation target.

### REFERENCE SIGNS LIST

1 Organic EL display device (Organic Electroluminescent Display Device)

2 Pixel

2B Sub-pixel

2G Sub-pixel

2R Sub-pixel

10 TFT substrate

11 Insulating substrate

12 TFT

13 Interlayer film

13a Contact hole

14 Wire

15 Edge cover

15R Opening

15G Opening

15B Opening

20 Organic EL element

21 First electrode

22 Hole injection layer/hole transfer layer

23R Luminescent layer

23G Luminescent layer

23B Luminescent layer

24 Electron transfer layer

25 Electron injection layer

26 Second electrode

30 Adhesive layer

40 Sealing substrate

50 Vapor deposition device

60 Film formation substrate

70 Shadow mask

80 Vapor deposition source

80A Vapor deposition source

80B Vapor deposition source

81 Injection hole

82 Vapor deposition source crucible (vapor deposition particle supplying means)

83a Pipe

83b Pipe

83c Pipe

83b Pipe

83d Pipe

83e Pipe

83f Pipe

83g Auxiliary pipe

84a Valve (supply control means)

84b Valve (supply control means)

84c Valve (supply control means)

84d Valve (supply control means)

84e Valve (supply control means)

84f Valve (supply control means)

90 Vacuum chamber

150 Vapor deposition device

170 Shadow mask

171 Opening

250 Vapor deposition device

260 Film formation substrate

270 Shadow mask

280 Vapor deposition source

281 Injection hole

282 Vapor deposition source crucible

283 Pipe

290 Vacuum chamber

P1 Introduction path

P2 Introduction path

P3 Introduction path

1. A vapor deposition device for forming a film on a film formation substrate, comprising:
a vapor deposition source which has a plurality of injection holes from which vapor deposition particles are to be injected towards the film formation substrate, the plurality of injection holes being arranged in one or more lines;
a plurality of pipes connected to the vapor deposition source; and
vapor deposition particle supplying means for supplying the vapor deposition particles to the vapor deposition source via the plurality of pipes,
the plurality of pipes including at least one pipe which is connected to a first side of the vapor deposition source on one end side of the one or more lines of the plurality of injection holes, and
the plurality of pipes including at least one pipe which is connected to a second side of the vapor deposition source on the other end side of the one or more lines of the plurality of injection holes.

2. The vapor deposition device according to claim 1, wherein each of the plurality of pipes is provided with supply control means for controlling an amount of the vapor deposition particles to be supplied to the vapor deposition source.

3. The vapor deposition device according to claim 2, wherein the vapor deposition particles are supplied to the vapor deposition source via any one of the plurality of pipes so as to be injected.

4. The vapor deposition device according to claim 1, wherein (i) the at least one pipe connected to the first side of the vapor deposition source on the one end side of the one or more lines of the plurality of injection holes and (ii) the at least one pipe connected to the second side of the vapor deposition source on the other end side of the one or more lines of the plurality of injection holes each include a plurality of pipes.

5. The vapor deposition device according to claim 1, wherein:
the plurality of injection holes are arranged in a matrix pattern;
the plurality of pipes include at least one pipe which is connected to a third side of the vapor deposition source on one end side of one or more rows of the plurality of injection holes; and
the plurality of pipes include at least one pipe which is connected to a fourth side of the vapor deposition source on the other end side of the one or more rows of the plurality of injection holes.

6. The vapor deposition device according to claim 1, further comprising:
an auxiliary pipe in addition to the plurality of pipes,
the vapor deposition particles supplying means supplying the vapor deposition particles to the vapor deposition source via the plurality of pipes and the auxiliary pipe, and
the auxiliary pipe being connected to a part of the vapor deposition source other than the first and second sides of the vapor deposition source on the one end side and the other end side, respectively, of the one or more lines of the plurality of injection holes.

7. The vapor deposition device according to claim 6, wherein the auxiliary pipe is connected to the vapor deposition source in an intermediate part of the arrangement of the plurality of injection holes.

8. The vapor deposition device according to claim 1, further comprising moving means for moving the film formation substrate relative to the vapor deposition source.

9. The vapor deposition device according to claim 1, wherein a direction in which the plurality of injection holes are arranged is perpendicular to a direction in which the film formation substrate is moved relative to the vapor deposition source.

10. A vapor deposition method for forming a film on a film formation substrate, comprising the steps of:
(a) while supplying, via a pipe, vapor deposition particles to a vapor deposition source which has a plurality of injection holes arranged in one or more lines, injecting the vapor deposition particles from the plurality of injection holes towards the film formation substrate, the pipe being connected to a first side of the vapor deposition source on one end side of the one or more lines of the plurality of injection holes; and
(b) after the step (a), while supplying, via a pipe, the vapor deposition particles to the vapor deposition source, injecting the vapor deposition particles from the plurality of injection holes towards the film formation substrate, the pipe being connected to a second side of the vapor deposition source on the other end side of the one or more lines of the plurality of injection holes.

11. A method for producing an organic electroluminescent display device, comprising the steps of:
(A) forming a first electrode on a TFT substrate;
(B) depositing, over the TFT substrate, an organic layer including at least a luminescent layer;
(C) depositing a second electrode; and
(D) sealing, with a sealing member, an organic electroluminescent element including the organic layer and the second electrode,
at least one of the steps (B), (C), and (D) including the steps (a) and (b) of the vapor deposition method recited in claim 10.
